(19) United States
(12) Patent Application Publication
(10) Pub. No.: US 2026/0026244 A1
(43) Pub. Date: Jan. 22, 2026

(54) DISPLAY DEVICE, METHOD OF MANUFACTURING DISPLAY DEVICE, AND ELECTRONIC DEVICE INCLUDING THE SAME

(71) Applicant: SAMSUNG DISPLAY CO., LTD., YONGIN-SI (KR)

(72) Inventors: Tae Ho KIM, Yongin-si (KR); Oh Jeong KWON, Yongin-si (KR); Dae Won KIM, Yongin-si (KR); Jong Ho SON, Yongin-si (KR); Mi Hwa LEE, Yongin-si (KR); Sung Gyu JANG, Yongin-si (KR)

(21) Appl. No.: 19/191,478

(22) Filed: Apr. 28, 2025

(30) Foreign Application Priority Data
Jul. 16, 2024 (KR) 10-2024-0093956

(51) Int. Cl. H10K 59/80; C08F 22/10; C09K 19/04; C09K 19/38; G02B 1/111; G02B 5/30; H10K 59/12; H10K 59/50

(52) U.S. Cl. CPC H10K 59/873; C08F 22/1006; C09K 19/3852; G02B 1/111; G02B 5/3016; H10K 59/1201; H10K 59/50; C09K 2019/0448

(57) ABSTRACT

A display device may include a display layer and a phase retardation layer disposed on the display layer. The phase retardation layer includes a first layer including a phase retarder, a second layer disposed on the first layer and including an inorganic material, and a third layer disposed on the second layer and including a polarizer. An upper surface of the first layer has a first wrinkle structure and contacts a lower surface of the second layer. An upper surface of the second layer has a second wrinkle structure and contacts a lower surface of the third layer.

This application claims priority to Korean Patent Application No. 10-2024-0093956, filed on Jul. 16, 2024 in the Korean Intellectual Property Office, the disclosure of which is incorporated by reference herein in its entirety.

### BACKGROUND

### 1. Field

The disclosure relates to a display device, a method of manufacturing the display device, and an electronic device including the same.

### 2. Description of the Related Art

Recently, as interest in information display is increased, research and development on a display device is continuously being conducted. The display device requires various optical characteristics. For example, it may be desirable to improve a viewing angle characteristic and the like so that display quality may be improved.

### SUMMARY

An aspect of the disclosure is to provide a display device and a method of manufacturing the display device, in which a risk of external light reflection may be reduced and display quality may be improved.

An aspect of the disclosure is to provide a display device and a method of manufacturing the display device, in which light emission efficiency and a viewing angle characteristic may be improved.

An aspect of the disclosure is to provide a display device and a method of manufacturing the display device, in which a risk of color shift in a lateral direction may be reduced.

According to an embodiment of the disclosure, a display device may include a display layer, and a phase retardation layer disposed on the display layer. The phase retardation layer includes a first layer including a phase retarder, a second layer disposed on the first layer and including an inorganic material, and a third layer disposed on the second layer and including a polarizer. An upper surface of the first layer has a first wrinkle structure and contacts a lower surface of the second layer. An upper surface of the second layer has a second wrinkle structure and contacts a lower surface of the third layer.

According to an embodiment, a curing degree of the first layer may be 70% to 90%.

According to an embodiment, the first layer may have a modulus value of 3.32 GPa or less.

According to an embodiment, the first wrinkle structure may have a shape of wave with a wavelength of 0.5 μm to 4 μm.

According to an embodiment, the first length may be 0.5 μm to 1.22 μm.

According to an embodiment, the shape of wave of the first wrinkle structure may have an amplitude of 48 nm to 100 nm.

According to an embodiment, the first wrinkle structure is substantially the same as the second wrinkle structure.

According to an embodiment, the phase retardation layer may have a specular component excluded (SCE) reflectance of 0.83% to 10% in a wavelength band of 380 nm to 780 nm.

According to an embodiment, the first layer may include a material having a phase retardation characteristic. The second layer may include silicon nitride (SixNy).

According to an embodiment, a lower surface of the third layer may have a shape which is substantially the same as the second wrinkle structure,

According to an embodiment, the display device may further include an orientation layer disposed on the display layer and including liquid crystal molecules. The first layer may be directly disposed on the orientation layer.

According to an embodiment, the display device may further include a touch sensor layer disposed on the display layer. The display layer may include a light emitting element and an encapsulation layer on the light emitting element. The touch sensor layer may be directly disposed on the encapsulation layer.

According to an embodiment of the disclosure, a method of manufacturing a display device may include providing a panel including a display layer, forming a first layer including a phase retarder and a second layer including an inorganic material on the panel, and forming a third layer including a polarizer on the second layer. An upper surface of the first layer may have a first wrinkle structure and contact a lower surface of the second layer. An upper surface of the second layer may have a second wrinkle structure and contact a lower surface of the third layer.

According to an embodiment, forming the first layer may include providing the first layer by performing a polymerization reaction of a reactive mesogen composition, and curing the first layer to form the first wrinkle structure.

According to an embodiment, the reactive mesogen composition may include a reactive mesogen, a crosslinking agent, a photoinitiator, an additive, and a solvent.

According to an embodiment, the reactive mesogen may include a material represented by the following chemical formula:

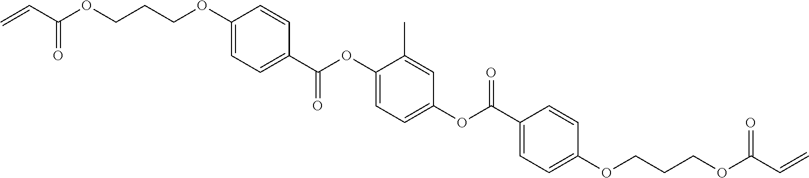 [SMILES: C=CC(=O)OCCCOc1ccc(C(=O)Oc2ccc(OC(=O)c3ccc(OCCCOC(=O)C=C)cc3)c(C)c2)cc1]

According to an embodiment, the curing of the first layer may be performed at a curing rate of 90% or less.

According to an embodiment, a modulus of the first layer to 3 GPa or less.

According to an embodiment, a lower surface of the third layer may have substantially the same shape as the second wrinkle structure.

According to an embodiment, the first wrinkle structure may be substantially the same as the second wrinkle structure.

According to an embodiment of the disclosure, an electronic device includes a display device and a power supply configured to provide power to the display device. The display device may include a display layer, and a phase retardation layer disposed on the display layer. The phase retardation layer includes a first layer including a phase retarder, a second layer disposed on the first layer and including an inorganic material, and a third layer disposed on the second layer and including a polarizer. An upper surface of the first layer has a first wrinkle structure and contacts a lower surface of the second layer. An upper surface of the second layer has a second wrinkle structure and contacts a lower surface of the third layer.

According to an embodiment of the disclosure, a display device and a method of manufacturing the display device, in which a risk of external light reflection may be reduced and display quality may be improved may be provided.

According to an embodiment of the disclosure, a display device and a method of manufacturing the display device, in which light emission efficiency and a viewing angle characteristic may be improved may be provided.

According to an embodiment of the disclosure, a display device and a method of manufacturing the display device, in which a risk of color shift in a lateral direction may be reduced may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIG. 3 is a schematic cross-sectional view illustrating a phase retardation layer according to an embodiment in more detail;

FIG. 4 is a flowchart illustrating a method of manufacturing a display device according to an embodiment;

FIGS. 5 and 6 are schematic cross-sectional views for each process step illustrating a method of manufacturing a display device according to an embodiment; and

FIG. 7 is a block diagram of an electronic device according to an embodiment.

FIG. 8 shows schematic views of various embodiments of an electronic device.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

Unless otherwise specified in this specification, a property of an object may be measured in a room temperature (25° C.) environment, and the object property may be measured based on equipment and a method known in the art

The disclosure relates to a display device and a method of manufacturing the display device. Hereinafter, a display device and a method of manufacturing the display device according to an embodiment are described with reference to the accompanying drawings.

### 1. DISPLAY DEVICE

The present inventive concept relates to a display device that includes a phase retardation layer of an in-cell polarizer. More specifically, the phase retardation layer may include a first layer including a retarder (which is also referred to as an in-cell retarder integrated into a display panel), a second layer formed of an inorganic film, and a third layer including a polarizer. To improve side brightness and a risk of color shift (white angular dependency (WAD)), wrinkles may be formed and maintained at an upper surface of the first layer by controlling a curing degree of the first layer, and such wrinkles are also formed on an upper surface of the second layer. At the curing degree of 70% to 90%, the above benefit can be achieved.

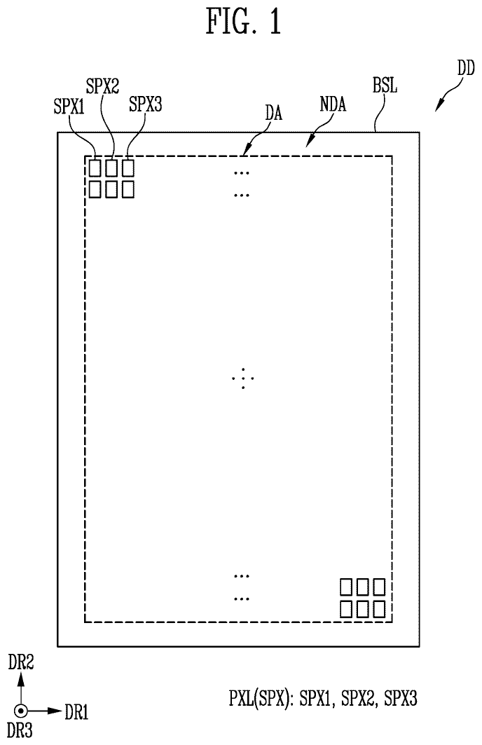

FIG. 1 is a schematic plan view illustrating a display device according to an embodiment.

Referring to FIG. 1, the display device DD may include a base layer BSL and a pixel PXL disposed on the base layer BSL. The display device DD may further include a driving circuit unit (for example, a scan driver and a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. According to an embodiment, the base layer BSL may be a lower substrate for disposing layers forming the display device DD. The base layer BSL may be a rigid or flexible substrate or film. For example, the base layer BSL may include a glass material. Alternatively, the base layer BSL may include a silicon material. Alternatively, the base layer BSL may include polyimide. However, the disclosure is not limited thereto.

A plane defined in the present specification may be defined based on a plane where the base layer BSL is disposed, as a direction extending in a first direction DR1 and a second direction DR2. According to an embodiment, a third direction DR3 may be a thickness direction of the base layer BSL, and the third direction DR3 may be a light emission direction of the display device DD.

The display area DA may mean an area where the pixel PXL is disposed. The non-display area NDA may mean an area where the pixel PXL is not disposed. The driving circuit unit, the line, and the pads connected to the pixel PXL of the display area DA may be disposed in the non-display area NDA.

According to an embodiment, the pixel PXL (or sub-pixels SPX) may be arranged according to a stripe or PENTILE™ arrangement structure, but are not limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of various colors.

Each of the first sub-pixel SPX1, the second sub-pixel SPX2, and the third sub-pixel SPX3 may emit light of one color. For example, the first sub-pixel SPX1 may be a red pixel emitting light of red (for example, first color), the second sub-pixel SPX2 may be a green pixel emitting light of green (for example, second color), and the third sub-pixel SPX3 may be a blue pixel emitting light of blue (for example, third color).

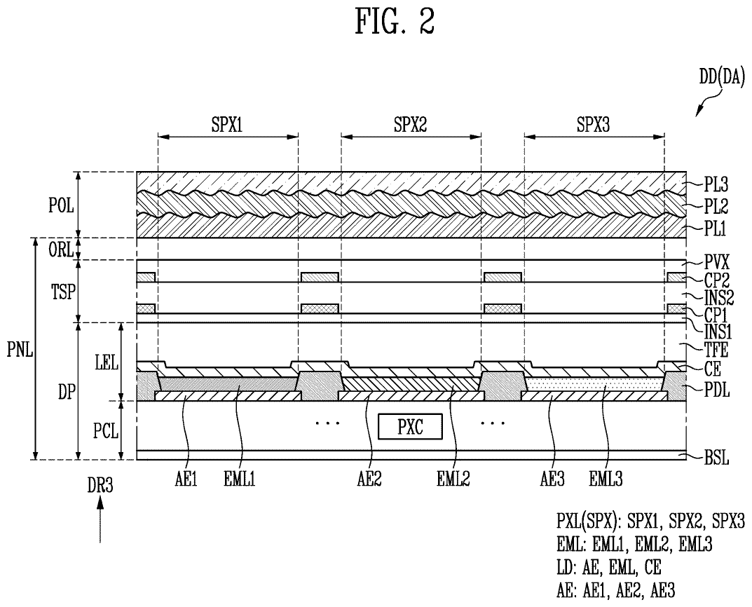

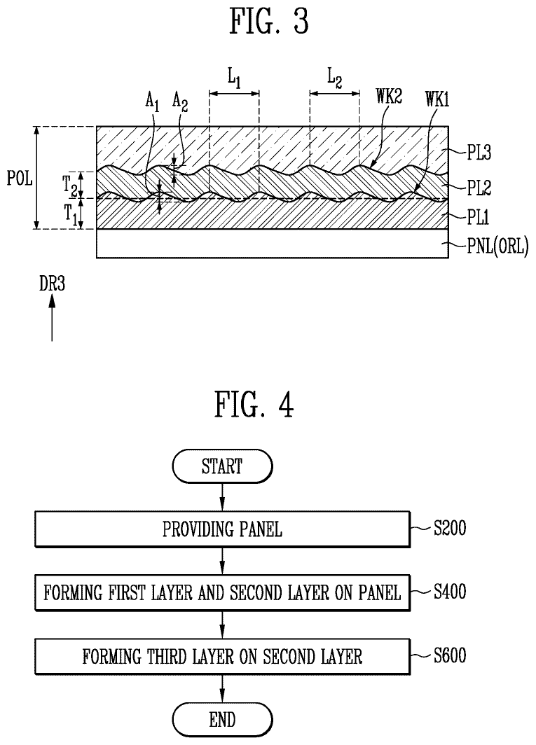

With reference to FIGS. 2 and 3, a cross-sectional structure of a display device DD according to an embodiment is described.

FIG. 2 is a schematic cross-sectional view illustrating a display device according to an embodiment. FIG. 3 is a schematic cross-sectional view illustrating a phase retardation layer according to an embodiment in more detail.

Referring to FIG. 2, the display device DD may include a panel PNL and a phase retardation layer POL on the panel PNL.

The panel PNL may include a display layer DP, a touch sensor layer TSP on the display layer DP, and an orientation layer ORL.

The display layer DP may include a base layer BSL, a pixel-circuit layer PCL including a pixel circuit PXC on the base layer BSL, and a light-emitting element layer LEL disposed on the pixel-circuit layer PCL and including a light emitting element LD, a pixel defining layer PDL, and an encapsulation layer TFE.

The pixel circuit PXC may be configured to drive a sub-pixel SPX and may be electrically connected to the light emitting element LD.

The light emitting element LD may include an anode electrode AE, an emission layer EML, and a cathode electrode CE. The light emitting element LD may be an organic light emitting diode. The emission layer EML may include a hole transport unit, a light emitting unit, and an electron transport unit.

The anode electrode AE may include first to third anode electrodes AE1 to AE3 included in the respective first to third sub-pixels SPX1 to SPX3. The emission layer EML may include first to third emission layers EML1 to EML3 included in the respective first to third sub-pixels SPX1 to SPX3. The cathode electrode CE may be a common electrode of the first to third sub-pixels SPX1 to SPX3.

The pixel defining layer PDL may expose a portion of the anode electrode AE and define an area where the emission layer EML is disposed.

The encapsulation layer TFE may encapsulate the light emitting elements LD. The encapsulation layer TFE may include an organic layer and an inorganic layer.

The touch sensor layer TSP may be disposed on the light-emitting element layer LEL. According to an embodiment, the touch sensor layer TSP may be directly disposed on the encapsulation layer TFE.

The touch sensor layer TSP may include a first insulating layer INS1, first and second conductive pattern layers CP1 and CP2, a second insulating layer INS2, and a protective layer PVX.

Each of the first and second conductive pattern layers CP1 and CP2 may be patterned in one area, and may form a sensing electrode. The formed sensing electrode may be driven based on a method of an electrostatic capacitance or the like, and may sense a user's touch input.

The first insulating layer INS1 may form a base on which the first and second conductive pattern layers CP1 and CP2 are disposed. The second insulating layer INS2 may be interposed between the first and second conductive pattern layers CP1 and CP2. The protective layer PVX may be disposed on the first and second conductive pattern layers CP1 and CP2.

The orientation layer ORL may be disposed on the touch sensor layer TSP. The orientation layer ORL may be disposed directly under the phase retardation layer POL. The orientation layer ORL may allow the display device DD to have intended display quality.

The orientation layer ORL may include various liquid crystal molecules. For example, the orientation layer ORL may be a layer manufactured by a photo-alignment method. For example, by aligning a polymer using ultraviolet light, a structure of liquid crystal molecules capable of forming the orientation layer ORL may be formed. According to an embodiment, the orientation layer ORL may be manufactured by applying UV light (for example, light having a wavelength of about 313 nm) to a cinnamate-based material. However, the disclosure is not limited thereto.

The phase retardation layer POL may be disposed on the panel PNL (for example, the orientation layer ORL). The phase retardation layer POL may be disposed across the first to third sub-pixels SPX1 to SPX3. The phase retardation layer POL may be disposed on the display layer DP.

According to an embodiment, since the phase retardation layer POL includes a phase retarder and a linear polarizer, an external light reflection light may be reduced, and since the phase retardation layer POL has a curved structure, a viewing angle characteristic of the display device DD may be improved.

According to an embodiment, the phase retardation layer POL may be referred to as a polarization structure layer. The phase retardation layer POL may be referred to as a light control layer.

According to an embodiment, the phase retardation layer POL may have an excellent reflectance characteristic. For example, the phase retardation layer POL may have a specular component excluded (SCE) reflectance of 0.83% to 10% in a wavelength band of 380 nm to 780 nm. The SCE reflectance may be measured in the SCE measurement mode of a spectrophotometer. In the SCE measurement mode, the specular reflected light is excluded and only the diffused light is measured, so that the measured value is similar to the sample color your eye would see.

The phase retardation layer POL may include a first layer PL1, a second layer PL2 on the first layer PL1, and a third layer PL3 on the second layer PL2. The first to third layers PL1 to PL3 may be directly adjacent to each other.

The first layer PL1 may be disposed on the panel PNL (for example, the orientation layer ORL). For example, the first layer PL1 may be directly disposed on the orientation layer ORL.

An upper surface of the first layer PL1 may have a curved structure or an uneven surface. For example, the upper surface of the first layer PL1 may have a first wrinkle structure WK1.

The first wrinkle structure WK1 of the first layer PL1 may have a periodic shape similarly to a wave shape.

According to an embodiment, the first layer PL1 may be a phase retarder (for example, a ¼λ phase retarder). According to an embodiment, the first layer PL1 may include a material having a hardness lower than a hardness of the second layer PL1. According to an embodiment, the first layer PL1 may include various phase retardation materials.

According to an embodiment, the first layer PL1 may have an in-plane phase retardation value of 100 nm to 500 nm. The in-plane retardation refers to the phase difference created between fast and slow axes of light as it passes through the first layer PL1, which includes an anisotropic material as a phase retardation material. The in-plane phase retardation value may refer to a degree of the in-plane retardation.

According to an embodiment, the first layer PL1 may include a material having a phase retardation characteristic manufactured using a reactive mesogen composition. For example, the first layer PL1 may include an acrylate-based bifunctional reactive mesogen. For example, the first layer PL1 may include a compound according to the following chemical formula 1.

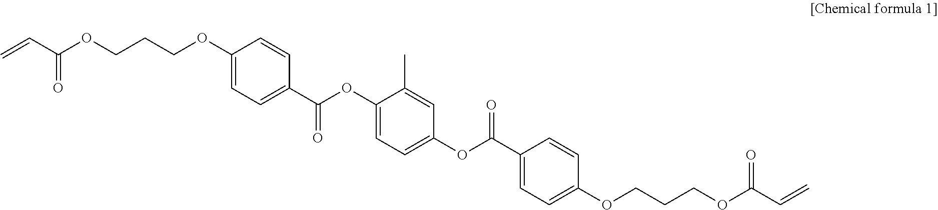 [SMILES: C=CC(=O)OCCCOc1ccc(C(=O)Oc2ccc(OC(=O)c3ccc(OCCCOC(=O)C=C)cc3)c(C)c2)cc1]

According to an embodiment, the phase retarder may be manufactured using a reactive mesogen composition.

The reactive mesogen composition according to an embodiment may include a reactive mesogen, a crosslinking agent, a photoinitiator, an additive, and a solvent.

In the present specification, materials included in the reactive mesogen composition excluding the solvent may be defined as a solid content. For example, according to an embodiment, the solid content of the reactive mesogen composition may include a reactive mesogen, a photoinitiator, and an additive.

The reactive mesogen may refer to a polymerizable mesogen. For example, the reactive mesogen may be polymerizable in an environment where ultraviolet light or the like is applied.

In an embodiment, the reactive mesogen may include at least one of a bismaleimide-based mesogen, an epoxy-based mesogen, an acrylate-based mesogen, a cyanovinyl-based mesogen, and a polyester-based mesogen. However, the disclosure is not limited thereto.

In an embodiment, the reactive mesogen may be contained in an amount of 10 wt % to 30 wt % with respect to the entire reactive mesogen composition.

The crosslinking agent may be provided to form a crosslink between materials in a reaction for polymerizing the reactive mesogen composition.

According to an embodiment, the crosslinking agent may include an epoxy-based crosslinking agent, an acrylate-based crosslinking agent, a silane-based crosslinking agent, or the like. However, an example of the crosslinking agent is not particularly limited.

In an embodiment, the crosslinking agent may be contained in an amount of 0.01 wt % to 3 wt % with respect to the entire reactive mesogen composition.

The photoinitiator may be provided to initiate a reaction for polymerizing the reactive mesogen composition. The photoinitiator may induce a polymerization reaction of the reactive mesogen composition to form a crosslink of the reactive mesogen.

According to an embodiment, the photoinitiator may include a first type photoinitiator that directly absorbs a photon to generate a reactive radical, a second type photoinitiator used together with a co-initiator, or the like. An example of the photoinitiator is not particularly limited. For example, the photoinitiator may include benzoin ether, acetophthone derivative, benzophthone-amine material, and the like.

According to an embodiment, the photoinitiator may be contained in an amount of 0.1 wt % to 3 wt % with respect to the entire reactive mesogen composition.

The additive may be provided to improve various characteristics of a polymerization reaction of the reactive mesogen composition. The additive may include a stabilizer, a plasticizer, a surfactant, or the like.

According to an embodiment, the additive is contained in an amount of 0.01 wt % to 1 wt % with respect to the entire reactive mesogen composition.

The solvent may include various organic solvents, in consideration of dispersibility of the reactive mesogen composition and solubility of materials forming the reactive mesogen composition. For example, the solvent may include an ether-based solvent, an alkyl acetate-based solvent, and the like, but the disclosure is not limited thereto.

According to an embodiment, the solvent may be contained in an amount of 69.88 wt % to 89.88 wt % with respect to the entire reactive mesogen composition.

According to an embodiment, the reactive mesogen composition may further include an additional material in addition to the materials described above. For example, the reactive mesogen composition may further include a monomer. According to an embodiment, the monomer may include at least one of an acrylate-based monomer, a vinyl-based monomer, an epoxy-based monomer, and a urethane monomer. However, the disclosure is not limited thereto.

According to an embodiment, manufacturing the first layer PL1 using the reactive mesogen composition may include inducing a polymerization reaction for the reactive mesogen, removing the solvent, and then performing a curing process. According to an embodiment, in performing the curing process during a process of manufacturing the first layer PL1, adjusting a curing degree of the first layer PL1 may be included. The curing degree refers to the extent to which a polymerization or crosslinking reaction has progressed in a material, such as resins, reactive mesogens, or thermosetting polymers. Determining the curing degree may be performed to evaluate the mechanical, thermal, and optical properties of the first layer PL1. In an embodiment, methods of measuring the curing degree may include Differential Scanning Calorimetry (DSC) or Fourier Transform Infrared Spectroscopy (FTIR).

According to an embodiment, the curing degree of the first layer PL1 may be adjusted, and thus whether or not the first wrinkle structure WK1 is formed and a structure of the first wrinkle structure WK1 may be adjusted. According to an embodiment, the curing degree of the first layer PL1 may be controlled using an applied amount of UV light during the curing process using ultraviolet (UV) light, a content and a type of the photoinitiator, a process time of the curing process, and a process environment (for example, a temperature and the like).

According to an embodiment, the curing degree of the first layer PL1 may be 70% to 90%. Alternatively, according to an embodiment, the curing degree of the first layer PL1 may be 70% to 80%. When the curing degree of the first layer PL1 is less than 70%, since the first layer PL1 is not sufficiently cured, reliability may be insufficient under a high temperature and high humidity environment, and when the curing degree of the first layer PL1 is greater than 90%, forming the first wrinkle structure WK1 in the first layer PL1 may be difficult. That is, according to an embodiment, when the curing degree of the first layer PL1 satisfies the above-described numerical range, reliability under a high temperature and high humidity environment may be secured, and the first wrinkle structure WK1 may be formed and maintained.

According to an embodiment, the first layer PL1 may have a modulus value of 3.32 GPa or less. The first layer PL1 may have a modulus value of 3.0 GPa or less.

According to an embodiment, the first wrinkle structure WK1 of the first layer PL1 may have a shape of a wave with a wavelength of a first length L₁. The first length L₁ may be a distance between adjacent ridges in the first wrinkle structure WK1 of the first layer PL1. The first length L₁ may be an average value of the first lengths L₁ defined in the first wrinkle structure WK1 of the first layer PL1.

According to an embodiment, the first length L₁ may be 0.5 μm to 4 μm. The first length L₁ may be 0.5 μm to 1.22 μm. When the first length L₁ satisfies the above-described numerical range, a risk of color shift in a lateral direction in the display device DD may be reduced.

According to an embodiment, the first wrinkle structure WK1 of the first layer PL1 may have an amplitude of a first height A₁. The amplitude refers to the maximum displacement or distance moved by a point on an upper surface of the first layer PL1. The first height A1 may be a height difference between a ridge and a valley in the first wrinkle structure WK1 of the first layer PL1. For example, the first height A1 may correspond to a height difference between a top of each wave in the first wrinkle structure WK1 and a bottom thereof. The first height A₁ may be an average value of the first heights A₁ defined in the first wrinkle structure WK1 of the first layer PL1.

According to an embodiment, the first height A₁ may be 48 nm to 100 nm. The first height A₁ may be 48 nm to 70 nm. When the first height A₁ satisfies the above-described numerical range, a risk of color shift in a lateral direction in the display device DD may be reduced.

According to an embodiment, the first wrinkle structure WK1 of the first layer PL1 may have a first thickness T₁. The first thickness T₁ may be an average thickness of the first layer PL1.

The second layer PL2 may be disposed on the first layer PL1. The second layer PL2 may be an inorganic layer including an inorganic material. For example, the second layer PL2 may include silicon nitride (SixNy). However, the disclosure is not limited thereto. According to an embodiment, the second layer PL2 may include at least one of silicon oxide (SixOy) and silicon oxynitride (SixOyNz). In some embodiments, the second layer PL2 may include at least one of silicon oxide (SixOy) or silicon oxynitride (SixOyNz).

According to an embodiment, the second layer PL2 may be a capping layer and may be a protective layer for the first layer PL1.

According to an embodiment, the second layer PL2 may have a compressive residual stress of 30 GPa or more. For example, the second layer PL2 may have a compressive residual stress of 30 GPa to 100 GPa. In this case, a second length L₂ for the second layer PL2 may be controlled to have a predetermined numerical range.

According to an embodiment, an upper surface of the second layer PL2 may have a curved structure or an uneven surface. For example, the upper surface of the second layer PL2 may have a second wrinkle structure WK2. In some embodiments, the second layer PL2 may be conformally formed on the upper surface of the first layer PL1, thereby the first wrinkle structure WK1 of the first layer PL being transferred to the second wrinkle structure WK2. For example, a bottom surface of the second layer PL2 may have substantially the same shape as the upper surface of the first layer PL1. The upper surface of the first layer PL1 and the bottom surface of the second layer PL2 may be substantially the same as the first wrinkle structure WK1. For example, the first height A₁ may be substantially the same as the second height A₂, and the first length L₁ may be substantially the same as the second length L₂. Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The second wrinkle structure WK2 of the second layer PL2 may have a periodic shape similarly to a wave shape.

According to an embodiment, the second wrinkle structure WK2 of the second layer PL2 may have a shape of a wave with a wavelength of a second length L₂. The second length L₂ may be a distance between adjacent ridges in the second wrinkle structure WK2 of the second layer PL2. The second length L₂ may be an average value of the second lengths L₂ defined in the second wrinkle structure WK2 of the second layer PL2.

According to an embodiment, the second wrinkle structure WK2 of the second layer PL2 may have an amplitude of a height A₂. The second height A₂ may be a height difference between a ridge and a valley in the second wrinkle structure WK2 of the second layer PL2. The second height A₂ may be an average value of the second heights A₂ defined in the second wrinkle structure WK2 of the second layer PL2.

According to an embodiment, the second wrinkle structure WK2 of the second layer PL2 may have a second thickness T₂. The second thickness T₂ may be an average thickness of the second layer PL2.

A lower surface of the second layer PL2 may have a shape corresponding to the first wrinkle structure WK1 of the first layer PL1. For example, the lower surface of the second layer PL2 may match or may be substantially the same as the upper surface of the first layer PL1.

According to an embodiment, the first and second wrinkle structures WK1 and WK2 may improve a viewing angle characteristic of the display device DD. For example, the first and second wrinkle structures WK1 and WK2 may form a curved interface in a light emission path provided by the light emitting element LD, and thus may scatter the light provided by the light emitting element LD. Accordingly, the display device DD may have an excellent viewing angle characteristic, and a risk of color shift (white angular dependency (WAD)) may be reduced. For example, the green tint in color, as an example of the color shift, at the edges of the display area AA may occur due to a phenomenon called WAD. The WAD may occur due to an inclined curved surface of the display area AA.

According to an embodiment, a dimension characteristic of the first and second wrinkle structures WK1 and WK2 may be required to be closely controlled so that the viewing angle characteristic may be further improved.

According to an embodiment, the dimension characteristic of the first and second wrinkle structures WK1 and WK2 may be adjusted according to the curing degree, the modulus, and the first and second thicknesses T1 and T2 for the first layer PL1.

In the present specification, unless otherwise specified, modulus means Young modulus.

According to an embodiment, the first length L₁ and the second length L₂ may correspond to each other. For example, the first length L₁ and the second length L₂ may be substantially equal to each other.

The first length L₁ or the second length L₂ may satisfy the following equation 1.

$${L}_{1} ( {L}_{2} ) = 2 π \sqrt{{T}_{1} {T}_{2}} {( \frac{{M}_{1}}{18 {M}_{2}} )}^{1 / 6} \qquad [ Equation 1 ]$$

Here, M₁ is a modulus value of the first layer PL1. M₂ is a modulus value of the second layer PL2.

In the present specification, the modulus value of each of the first layer PL1 and the second layer PL2 may be measured in a room temperature (25° C.) environment.

The modulus value of each of the first layer PL1 and the second layer PL2 may be measured by various generally known methods. For example, the modulus value of each of the first layer PL1 and the second layer PL2 may be measured based on nanoindentation, a tensile test, an ultrasonic measurement, or the like. However, the disclosure is not limited to a specific example.

Referring to equation 1, it may be confirmed that the first length L₁ and the second length L₂ representing a periodic characteristic of the first and second wrinkle structures WK1 and WK2 may be defined by the modulus value of each of the first layer PL1 and the second layer PL2, and the first and second thicknesses T1 and T2 of the respective first layer PL1 and second layer PL2.

Experimentally, the modulus value of each of the first layer PL1 and the second layer PL2 may be changed according to the curing degree or the like of each of layers. That is, it may be seen that the first length L₁ and the second length L₂ may be adjusted by adjusting the curing degree of the first layer PL1 and the like.

According to an embodiment, the first height A₁ and the second height A₂ may correspond to each other. For example, the first height A₁ and the second height A₂ may be substantially equal to each other.

The first height A₁ or the second height A₂ may satisfy the following equation 2.

$${A}_{1} ( {A}_{2} ) = {T}_{2} \sqrt{\frac{ε - {ε}_{c}}{{ε}_{c}}} \qquad [ Equation 2 ]$$

Here, ε is a strain measured when the first layer PL1 and the second layer PL2 are formed. ε_{c} is a critical strain when the first layer PL1 and the second layer PL2 are formed.

The critical strain ε_{c} may be a strain at a time point where an object material reaches a strain limit.

The critical strain ε_{c} may satisfy the following equation 3.

$${ε}_{c} = \frac{1}{4} {( \frac{3 {M}_{1}}{{M}_{2}} )}^{2 / 3} \qquad [ Equation 3 ]$$

Referring to equations 2 and 3, it may be confirmed that the first height A₁ and the second height A₂ representing information on a size of the first and second wrinkle structures WK1 and WK2 may be defined by the modulus value of each of the first layer PL1 and the second layer PL2, and the second thickness T₂ of the second layer PL2.

Experimentally, the modulus value of each of the first layer PL1 and the second layer PL2 may be changed according to the curing degree of each of layers. That is, it may be seen that the first height A₁ and the second height A₂ may be adjusted by adjusting the curing degree of the first layer PL1 and the like.

The third layer PL3 may be disposed on the second layer PL2. The third layer PL3 may include a polarizer. The third layer PL3 may include a linear polarizer. For example, the third layer PL3 may be a linear polarizer coated on the second layer PL2, and in another example, the third layer PL3 may be a film-type linear polarizer disposed on the second layer PL2.

An upper surface of the third layer PL3 may have a generally flat shape. According to an embodiment, a lower surface of the third layer PL3 may have a shape corresponding to the second wrinkle structure WK2 of the second layer PL2. For example, the lower surface of the third layer PL3 may match or may be substantially the same as the upper surface of the second layer PL2. For example, the lower surface of the third layer PL3 may have the second wrinkle structure WK2.

### 2. METHOD OF MANUFACTURING DISPLAY DEVICE

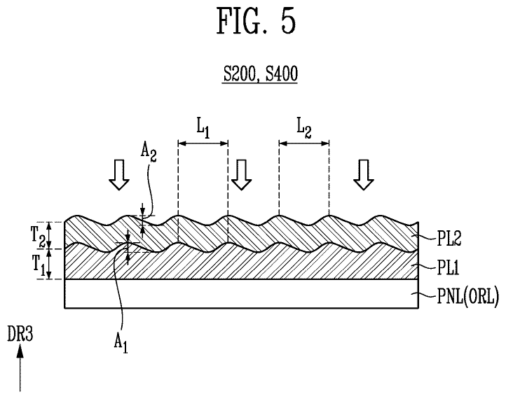

Hereinafter, with reference to FIGS. 4 to 6, a method of manufacturing a display device DD according to an embodiment is described. For convenience of description, a content that may overlap the content described above is briefly described or is not repeated.

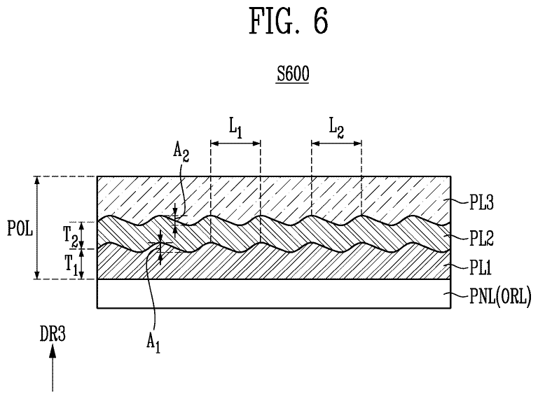

FIG. 4 is a flowchart illustrating a method of manufacturing a display device according to an embodiment. FIGS. 5 and 6 are schematic cross-sectional views for each process step illustrating a method of a display device according to an embodiment.

Referring to FIG. 4, the method of manufacturing the display device DD may include providing a panel (S200), forming a first layer and a second layer on the panel (S400), and forming a third layer on the second layer (S600).

Referring to FIG. 4 and FIG. 5 in conjunction with FIG. 2, in providing the panel (S200), a panel PNL including the display layer DP including the light emitting element LD capable of providing light may be provided.

In step S200, the pixel circuit PXC may be patterned on the base layer BSL, the light emitting element LD may be formed, and thus the display layer DP including the pixel-circuit layer PCL and the light-emitting element layer LEL may be manufactured. According to an embodiment, the first and second conductive pattern layers CP1 and CP2 may be patterned on the display layer DP, and thus the touch sensor layer TSP may be manufactured. According to an embodiment, the orientation layer ORL may be disposed on the touch sensor layer TSP. According to an embodiment, the orientation layer ORL may be omitted.

According to an embodiment, a conductive layer or an insulating layer on the base layer BSL may be formed based on a typical process for manufacturing a semiconductor device. For example, the conductive layer or the insulating layer on the base layer BSL may be formed by a photolithography process, etched by various methods (wet etching, dry etching, and the like), and deposited by various methods (sputtering, chemical vapor deposition, and the like). The disclosure is not necessarily limited to a specific example.

Referring to FIGS. 4 and 5, in forming the first layer and the second layer on the panel (S400), the first layer PL1 and the second layer PL2 may be sequentially disposed on the panel PNL (for example, the orientation layer ORL).

In step S400, the first layer PL1 may be disposed on the panel PNL using a reactive mesogenic composition according to an embodiment.

In step S400, a reactive mesogenic composition according to an embodiment may be disposed (for example, coated) on the panel PNL (for example, the orientation layer ORL), a polymerization reaction may be performed, and thus the first layer PL1 may be provided.

In step S400, a solvent may be removed after the polymerization reaction for the reactive mesogenic composition. For example, the solvent may be removed through a soft bake process.

In step S400, a curing step for the first layer PL1 may be performed after the solvent is removed. For example, UV light may be applied to the first layer PL1 so that the first layer PL1 may be photocured.

In step S400, a post-curing step may be performed after the curing step for the first layer PL1. For example, the solvent may be removed through a post bake step.

According to an embodiment, the curing degree of the first layer PL1 may be adjusted, and thus the first layer PL1 may be manufactured to have the first wrinkle structure WK1 having a predetermined numerical range. As described above, the first layer PL1 may be controlled to have a curing degree of 70% to 90%. Alternatively, according to an embodiment, the first layer PL1 may be controlled to have a curing degree of 70% to 80%. For example, adjusting the curing degree for the first layer PL1 may include forming the first wrinkle structure WK1 for the first layer PL1.

According to an embodiment, the curing degree of the first layer PL1 may be controlled to 90% or less, and the modulus of the first layer PL1 may be controlled to 3.32 GPa or less (or 3 GPa or less) so that the first wrinkle structure WK1 is formed in the first layer PL1. For example, according to an embodiment, the modulus of the first layer PL1 may be 0.5 GPa to 3.32 GPa. According to an embodiment, the modulus of the first layer PL1 may be 0.5 GPa to 3 GPa.

In step S400, the second layer PL2 including an inorganic material may be disposed on the first layer PL1. The second layer PL2 may also include the second wrinkle structure WK2, and a lower surface of the second layer PL2 may have a shape corresponding to the first wrinkle structure WK1. According to an embodiment, the lower surface of the second layer PL2 may be in contact with an upper surface of the first layer PL1. According to an embodiment, the second layer PL2 may be manufactured by a plasma enhanced chemical vapor deposition (PECVD) process. For example, in the PECVD process, the second layer PL2 may be conformally deposited on the upper surface of the first layer PL1. The shape of the upper surface of the first layer PL1 may be transferred to the second layer PL2, thereby an upper surface of the second layer PL2 having substantially the same shape as the upper surface of the first layer PL1. However, the disclosure is not limited thereto.

Referring to FIGS. 4 and 6, in forming the third layer on the second layer, the third layer PL3 may be disposed on the second layer PL2, and the phase retardation layer POL according to an embodiment may be provided.

In step S600, the third layer PL3 forming a linear polarizer may be disposed on the second layer PL2. For example, the third layer PL3 may be coated on the second layer PL2, and according to an embodiment, the third layer PL3 may have a film shape and may be disposed on the second layer PL2. According to an embodiment, in step S600, a lower surface of the third layer PL3 may be patterned to correspond to the second wrinkle structure WK2. The present disclosure is not limited thereto. In an embodiment, the third layer PL3 may be deposited on the upper surface of the second layer having the second wrinkle structure. A planarization process may be applied so that an upper surface of the third layer PL3 is planarized (i.e., has a flat surface). In step S600, the lower surface of the third layer PL3 may be in contact with an upper surface of the second layer PL2.

Thereafter, a window layer WD and the like may be further disposed according to an embodiment, and the display device DD according to an embodiment may be provided.

### 3. EXPERIMENTAL EXAMPLE

Hereinafter, the disclosure is described in more detail based on the experimental example. However, the following experimental example is merely an example for describing the disclosure in more detail, and the disclosure is not limited to an embodiment manufactured according to the following manufacturing example.

### (1) Experimental Example 1—Whether Wrinkle Structure is Formed According to Curing Rate and Modulus

The phase retardation layers (POL) according to manufacturing examples 1 to 3 and a comparative example were manufactured.

The first to third layers PL1 to PL3 of each of the phase retardation layers POL according to the manufacturing examples 1 to 3 and the comparative example were manufactured to include the same material, but the curing rates or moduli of the first layers PL1 of the manufacturing examples 1 to 3 and the comparative example were different.

The curing rates, the moduli, and whether the wrinkle structure is formed for the manufactured phase retardation layers POL are shown in Table 1.

The curing rate was measured by Fourier transform infrared spectroscopy (FTIR) and differential scanning calorimeter (DSC). The modulus was measured using a nano-indenter. In addition, whether the wrinkle structure is formed was determined by observing a cross-sectional and a planar image of the manufactured phase retardation layer POL.

TABLE 1

| | Manufac- | Manufac- | Manufac- | Compar- |
|---|---|---|---|---|
| Classifi- | turing | turing | turing | ative |
| cation | example 1 | example 2 | example 3 | example |
| Curing rate | 87.1 | 85 | 85 | 94.9 |
| (%) | | | | |
| Modulus (GPa) | 2.82 | 2.2 | 1.7 | 3.32 |
| Whether | ◯ | ◯ | ◯ | X |
| wrinkle | | | | |
| structure is | | | | |
| formed | | | | |

Referring to Table 1, when the curing rate of the first layer PL1 was 94.9% or less (for example, 90% or less), the wrinkle structure was formed in the phase retardation layer POL. In addition, when the modulus of the first layer PL1 is 3.32 GPa (for example, 3 GPa or less) during a manufacturing process of the first layer PL1, the wrinkle structure was formed in the phase retardation layer POL.

### (2) Experimental Example 2—Optical Characteristic Analysis According to Wrinkle Structure

The phase retardation layers POL according to the manufacturing examples 1 to 3 and the comparative example were manufactured.

The first to third layers PL1 to PL3 of each of the phase retardation layers POL according to the manufacturing examples 1 to 3 and the comparative example were manufactured to include the same material, but the manufacturing examples 1 to 3 and comparative example were different in the curing rates and moduli.

The curing rates, the first length L₁, the first height A₁, the SCE reflectance, and color shift data for the manufactured phase retardation layers POL are shown in Table 2.

The curing rate and the modulus were measured in a manner identically to the manner described in the experimental example 1.

The first length L₁ and the first height A₁ of the first wrinkle structure WK1 were measured in each of the first layers PL1 of the phase retardation layers POL according to the manufacturing examples 1 to 3. The first length L₁ and the first height A₁ of the first wrinkle structure WK1 were measured using a focused ion beam-scanning electron microscope (FIB-SEM).

The specular component excluded (SCE) reflectance was measured by a spectrophotometer, and light in a visible light wavelength band (light having a wavelength of approximately 380 nm to 780 nm) was used as a light source for measuring the SCE reflectance. The SCE reflectance may be measured in the SCE measurement mode of a spectrophotometer. In the SCE measurement mode, the specular reflected light is excluded and only the diffused light is measured, so that the measured value is similar to the sample color your eye would see.

The color shift Δu′v′ was calculated based on the international commission on Illumination (CIE) 1931 color coordinates, and the color coordinates were measured by a spectrophotometer. Specifically, the color coordinates of the light measured from the front of the display device DD may be measured as (u1′, v1′), the color coordinates of the light measured in a 60 degree viewing angle area may be measured as (u2′, v2′), and the color shift Δu′v′ between the front measurement and the measurement at the 60 degree viewing angle may be calculated as \sqrt{(u′₁−u′₂)²+(v′₁−v′₂)²}. The viewing angle may be measured with reference to the normal direction of the display area DA of the display device DD. For example, the front measurement is performed at the viewing angle of 0 degree.

TABLE 2

| | Manufac- | Manufac- | Manufac- | Compar- |
|---|---|---|---|---|
| Classifi- | turing | turing | turing | ative |
| cation | example 1 | example 2 | example 3 | example |
| Curing rate (%) | 73 | 80 | 85 | 92 |
| First length | 0.64 | 1.22 | 1.41 | — |
| (L₁)(μm) | | | | |
| First width | 78 | 48 | 27 | — |
| (A₁)(nm) | | | | |
| SCE reflectance | 3.02 | 1.72 | 0.83 | 0.08 |
| (%) | | | | |
| Color shift (Δ | 0.014 | 0.019 | 0.021 | 0.021 |
| u′v′) | | | | |
| (0~60 degrees) | | | | |

Referring to Table 2, in the phase retardation layer according to the comparative example, the wrinkle structure was not formed at the upper surface of the first layer PL1 which was cured at a curing rate of 92%. In addition, the phase retardation layer POL according to the manufacturing example had an excellent reflectance characteristic compared to the phase retardation layer according to the comparative example. The phase retardation layer POL according to the manufacturing example had a reduced color shift risk compared to the phase retardation layer according to the comparative example. In particular, it may be seen that the color shift risk was particularly reduced when the first length L₁ is 1.22 μm or less and the first height A₁ is 48 nm or more. As a result, the display device DD according to an embodiment may have an improved viewing angle characteristic, thereby reducing the color shift risk, and may have excellent display quality as the display device DD has an excellent reflectance characteristic.

A display device according to an embodiment is applicable to various types of electronic devices. In an embodiment, an electronic device includes the above-described display device and may further include other modules or devices having additional functions in addition to the display device.

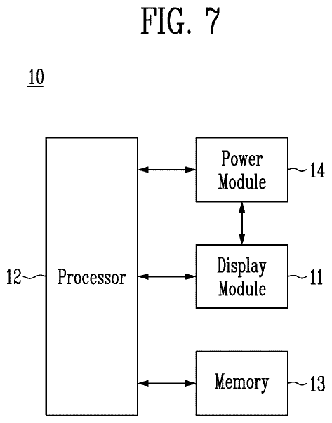

FIG. 7 is a block diagram of an electronic device according to an embodiment. Referring to FIG. 7, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10 (e.g., display module 11).

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

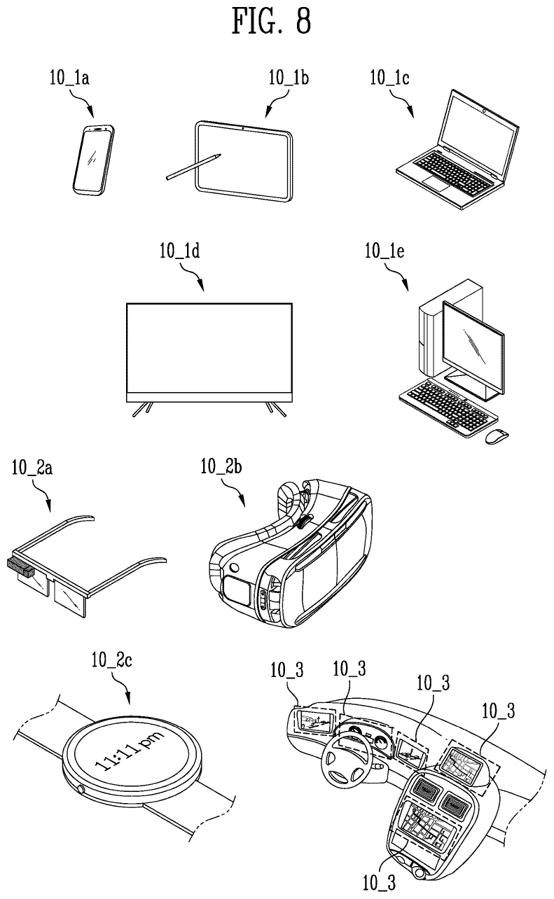

FIG. 8 shows schematic views of various embodiments of an electronic device.

Referring to FIG. 8, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

As described above, although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a display layer; and
a phase retardation layer disposed on the display layer,
wherein the phase retardation layer includes:
a first layer including a phase retarder,
a second layer disposed on the first layer and including an inorganic material, and
a third layer disposed on the second layer and including a polarizer,
wherein an upper surface of the first layer has a first wrinkle structure and contacts a lower surface of the second layer, and
wherein an upper surface of the second layer has a second wrinkle structure and contacts a lower surface of the third layer.

2. The display device of claim 1,
wherein a curing degree of the first layer is 70% to 90%.

3. The display device of claim 1,
wherein the first layer has a modulus value of 3.32 GPa or less.

4. The display device of claim 1,
wherein the first wrinkle structure has a shape of a wave with a wavelength of 0.5 μm to 4 μm.

5. The display device of claim 4,
wherein the wavelength is 0.5 μm to 1.22 μm.

6. The display device of claim 4,
wherein the shape of the wave of the first wrinkle structure has a first amplitude of 48 nm to 100 nm.

7. The display device of claim 1,
wherein the first wrinkle structure and the second wrinkle structure have a same amplitude.

8. The display device of claim 1,
wherein the phase retardation layer has a specular component excluded (SCE) reflectance of 0.83% to 10% in a wavelength band of 380 nm to 780 nm.

9. The display device of claim 1,
wherein the first layer includes a material having a phase retardation characteristic, and
wherein the second layer includes silicon nitride (SixNy).

10. The display device of claim 1,
wherein a lower surface of the third layer has a shape which is substantially the same as the second wrinkle structure.

11. The display device of claim 1, further comprising:
an orientation layer disposed on the display layer and including liquid crystal molecules; and
a touch sensor layer disposed on the display layer,
wherein the first layer is directly disposed on the orientation layer,
wherein the display layer includes a light emitting element and an encapsulation layer on the light emitting element, and
wherein the touch sensor layer is directly disposed on the encapsulation layer.

12. A method of manufacturing a display device, the method comprising:
providing a panel including a display layer;
forming a first layer including a phase retarder and a second layer including an inorganic material on the panel; and
forming a third layer including a polarizer on the second layer,
wherein an upper surface of the first layer has a first wrinkle structure and contacts a lower surface of the second layer, and
wherein an upper surface of the second layer has a second wrinkle structure and contacts a lower surface of the third layer.

13. The method of claim 12,
wherein forming the first layer comprises:
providing the first layer by performing a polymerization reaction of a reactive mesogen composition; and
curing the first layer to form the first wrinkle structure.

14. The method of claim 13,
wherein the reactive mesogen composition includes a reactive mesogen, a crosslinking agent, a photoinitiator, an additive, and a solvent.

15. The method of claim 14,
wherein the reactive mesogen includes a material represented by the following chemical formula:

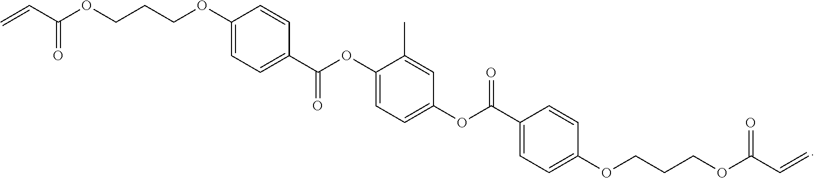 [SMILES: C=CC(=O)OCCCOc1ccc(C(=O)Oc2ccc(OC(=O)c3ccc(OCCCOC(=O)C=C)cc3)c(C)c2)cc1]

16. The method of claim 13,
wherein the curing of the first layer is performed at a curing rate of 90% or less.

17. The method of claim 14,
wherein a modulus of the first layer has 3 GPa or less.

18. The method of claim 12,
wherein a lower surface of the third layer has substantially the same shape as the second wrinkle structure of the second layer.

19. The method of claim 18,
wherein the first wrinkle structure and the second wrinkle structure have a same amplitude.

20. An electronic device, comprising:
a display device; and
a power supply configured to provide power to the display device,
wherein the display device comprises:
a display layer; and
a phase retardation layer disposed on the display layer,
wherein the phase retardation layer includes:
a first layer including a phase retarder,
a second layer disposed on the first layer and including an inorganic material, and
a third layer disposed on the second layer and including a polarizer,
wherein an upper surface of the first layer has a first wrinkle structure and contacts a lower surface of the second layer, and
wherein an upper surface of the second layer has a second wrinkle structure and contacts a lower surface of the third layer.
